(19) United States
(12) Patent Application Publication
(10) Pub. No.: US 2017/0311445 A1
(43) Pub. Date: Oct. 26, 2017

(54) ELECTRONIC PACKAGE AND SUBSTRATE STRUCTURE THEREOF

(71) Applicant: Siliconware Precision Industries Co., Ltd., Taichung (TW)

(72) Inventors: Hung-Hsien Chang, Taichung (TW); Jyun-Ling Tsai, Taichung (TW); Yu-Ling Yeh, Taichung (TW); Wen-Tsung Tseng, Taichung (TW); Yi-Che Lai, Taichung (TW)

(21) Appl. No.: 15/226,996

(22) Filed: Aug. 3, 2016

(30) Foreign Application Priority Data
Apr. 22, 2016 (TW) 105112586

(51) Int. Cl. H05K 1/14; H05K 1/11

(52) U.S. Cl. CPC H05K 1/144; H05K 1/11

(57) ABSTRACT

A substrate structure is provided, which includes a substrate having a plurality of conductors and at least a receiving space formed on a surface of the substrate with the receiving space free from penetrating the substrate. During an encapsulating process, an encapsulant can be filled in the receiving space so as to strengthen the bonding between the substrate and the encapsulant, thereby preventing delamination from occurring therebetween.

### BACKGROUND

### 1. Technical Field

The present disclosure relates to semiconductor packaging processes, and, more particularly, to an electronic package and a substrate structure thereof with improved product yield.

### 2. Description of Related Art

Along with the rapid development of electronic industries, electronic products are developed toward the trend of multi-function and high performance. Accordingly, there have been developed various types of flip-chip packaging modules, such as chip scale packages (CSPs), direct chip attached (DCA) packages and multi-chip modules (MCM), and 3D IC chip stacking modules.

FIG. 1 is a schematic cross-sectional view of a conventional 3D IC semiconductor package 1. Referring to FIG. 1, a semiconductor chip 13 is disposed on a silicon interposer 12 through a plurality of solder bumps 130. The silicon interposer 12 has a plurality of through silicon vias (TSVs) 120, and a redistribution layer 121 formed on the TSVs 120 and electrically connected to the solder bumps 130. The silicon interposer 12 is further bonded to a packaging substrate 11 through the TSVs 120 and a plurality of conductive elements 110. An underfill 10′ is formed to encapsulate the conductive elements 110 and the solder bumps 130, and an encapsulant 10 is formed to encapsulate the semiconductor chip 13 and the silicon interposer 12.

However, when temperature cycling or stress variation occurs in a reflow process or a drop test, for example, the semiconductor chip 13 and the silicon interposer 12 are likely delaminated from the encapsulant 10 or the underfill 10′ due to a CTE (Coefficient of Thermal Expansion) mismatch therebetween, thus adversely affecting the electrical connection between the silicon interposer 12 and the semiconductor chip 13 or resulting in failure of a reliability test and hence reducing the product yield.

Therefore, how to overcome the above-described drawbacks has become critical.

### SUMMARY

In view of the above-described drawbacks, the present disclosure provides a substrate structure, which comprises: a substrate having a plurality of conductors; and at least a receiving space formed on a surface of the substrate with the receiving space free from penetrating the substrate.

In an embodiment, the substrate is a semiconductor board or a ceramic board.

In an embodiment, the substrate has a first surface, a second surface opposite to the first surface, and a side surface adjacent to and connecting the first surface and the second surface, and the receiving space is formed on at least one of the first surface, the second surface and the side surface of the substrate.

In an embodiment, the substrate has at least a corner, and the receiving space is formed at the corner.

In an embodiment, the conductors are circuit layers, conductive posts, conductive bumps, or any combination thereof.

In an embodiment, the receiving space has an opening that is greater than 3 μm in width.

In an embodiment, the receiving space has a wide opening and a narrow inner portion. In another embodiment, the receiving space has a narrow opening and a wide inner portion.

The present disclosure further provides an electronic package, which comprises: at least a first substrate having a plurality of first conductors; at least a second substrate bonded to the first substrate and having a plurality of second conductors; at least a receiving space formed on a surface of the first substrate or the second substrate with the receiving space free from penetrating the first substrate and the second substrate; and a packaging body formed on the first substrate and filling the receiving space with a filler of the packaging body.

In an embodiment, the first substrate is a semiconductor board or a ceramic board. In an embodiment, the second substrate is a semiconductor board or a ceramic board.

In an embodiment, the first substrate has a first surface, a second surface opposite to the first surface, and a side surface adjacent to and connecting the first surface and the second surface, and the receiving space is formed on at least one of the first surface, the second surface and the side surface of the first substrate. The second substrate has a third surface, a fourth surface opposite to the third surface, and a side surface adjacent to and connecting the third surface and the fourth surface, and the receiving space is formed on at least one of the third surface, the fourth surface and the side surface of the second substrate.

In an embodiment, the first substrate has at least a corner, and the receiving space is formed at the corner. The second substrate has at least a corner, and the receiving space is formed at the corner.

In an embodiment, the first conductors and the second conductors are circuit layers, conductive posts, conductive bumps, or any combination thereof.

In an embodiment, the first conductors are electrically connected to the second conductors.

In an embodiment, the receiving space has an opening that has a width greater than a particle size of the filler of the packaging body. In another embodiment, the receiving space has an opening that is greater than 3 μm in width.

In an embodiment, the receiving space has a wide opening and a narrow inner portion. In another embodiment, the receiving space has a narrow opening and a wide inner portion.

In an embodiment, the packaging body covers the first substrate and/or the second substrate.

In an embodiment, the package further comprises at least a third substrate bonded to the second substrate. The receiving space is formed on the first substrate, the second substrate and/or the third substrate with the receiving space free from penetrating the first substrate, the second substrate and the third substrate.

Therefore, by forming a receiving space on a substrate, the present disclosure allows the material of the packaging body to be filled in the receiving space during formation of the packaging body, thereby strengthening bonding between the substrate and the packaging body and preventing delamination from occurring therebetween.

### BRIEF DESCRIPTION OF DRAWINGS

FIG. 1 is a schematic cross-sectional view of a conventional semiconductor package;

FIG. 2 is a schematic cross-sectional view of an electronic package according to the present disclosure;

FIGS. 3A to 3C are schematic cross-sectional views showing formation of a receiving space of a substrate structure at various stages according to the present disclosure;

FIG. 4 is a schematic cross-sectional view showing receiving spaces of various shapes according to the present disclosure;

FIGS. 5A to 5H are schematic upper views of a substrate structure according to various embodiments of the present disclosure;

FIGS. 6A to 6C are schematic upper views of a substrate according to various embodiments of the present disclosure; and

FIG. 6C′ is a schematic cross-sectional view taken along a sectional line A-A′ of FIG. 6C.

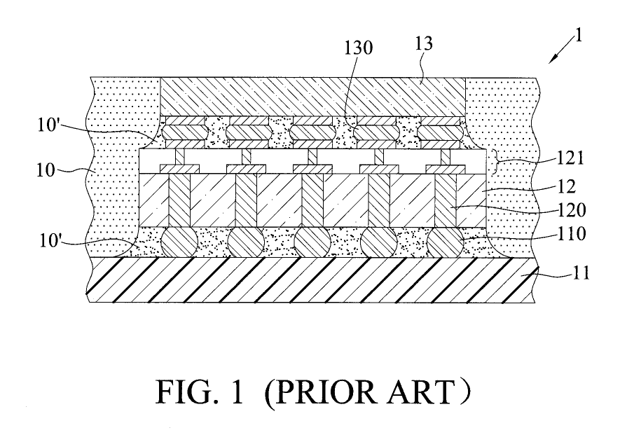

### DETAILED DESCRIPTIONS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a,” etc. are merely for illustrative purposes and should not be construed to limit the scope of the present disclosure.

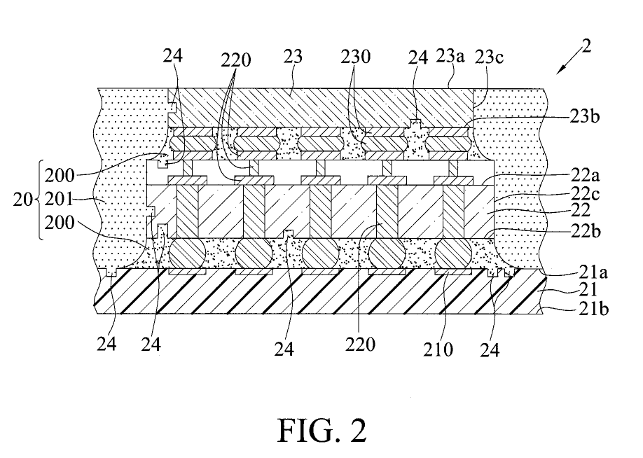

FIG. 2 is a schematic cross-sectional view of an electronic package 2 according to the present disclosure. The electronic package 2 comprises a first substrate 21, a second substrate 22 disposed on the first substrate 21, a third substrate 23 disposed on the second substrate 22, at least a receiving space 24 formed on the first substrate 21, the second substrate 22 or the third substrate 23, and a packaging body 20 disposed on the first substrate 21 and filling the receiving space 24.

The first substrate 21 has a plurality of first conductors 210. In an embodiment, the first substrate 21 is a ceramic board that serves as a packaging substrate, and the first conductors 210 are circuit layers, conductive posts or conductive bumps.

The first substrate 21 has a first surface 21a, a second surface 21b opposite to the first surface 21a, and a side surface adjacent to and connecting the first surface 21a and the second surface 21b.

The second substrate 22 has a plurality of second conductors 220, and the third substrate 23 has a plurality of third conductors 230. In an embodiment, the second substrate 22 and the third substrate 23 are semiconductor boards. The second substrate 22 serves as an interposer that is disposed on the first substrate 21, and the third substrate 23 serves as an electronic component that is disposed on the second substrate 22. The second conductors 220 and the third conductors 230 are circuit layers, conductive posts or conductive bumps. In an embodiment, the third substrate 23 (an electronic component) is an active component such as a semiconductor chip, a passive component, such as a resistor, a capacitor or an inductor, or a combination thereof.

The second substrate 22 has a third surface 22a, a fourth surface 22b opposite to the third surface 22a, and a side surface 22c adjacent to and connecting the third surface 22a and the fourth surface 22b. Similarly, the third substrate 23 has a fifth surface 23a, a sixth surface 23b opposite to the fifth surface 23a, and a side surface 23c adjacent to and connecting the fifth surface 23a and the sixth surface 23b.

Further, the second conductors 220 and the third conductors 230 are electrically connected to the first conductors 210.

The receiving space 24 can be formed on the first substrate 21, the second substrate 22 and/or the third substrate 23, without penetrating the first substrate 21, the second substrate 22 or the third substrate 23.

In an embodiment, the receiving space 24 is formed on at least one of the first surface 21a, the second surface 21b and the side surface of the first substrate 21, and further formed on at least one of the third surface 22a, the fourth surface 22b and the side surfaces 22c of the second substrate 22 and the fifth surface 23a, the sixth surface 23b and the side surfaces 23c of the third substrate 23.

In an embodiment, the first substrate 21, the second substrate 22 or the third substrate 23 has at least a corner, and the receiving space 24 is formed on the corner.

The packaging body 20 is formed on the first substrate 21 to encapsulate the second substrate 22 and the third substrate 23 and fill the receiving space 24.

In an embodiment, the packaging body 20 includes an underfill 200 formed between the first substrate 21 and the second substrate 22 and between the second substrate 22 and the third substrate 23, and an encapsulant 201 formed on the first surface 21a of the first substrate 21 to encapsulate the second substrate 22 and the third substrate 23.

Therefore, the receiving space 24 formed on at least a surface of the first substrate 21, the second substrate 22 and the third substrate 23 allows the material of the packaging body 20 (an underfill or an encapsulant) to be filled therein during formation of the packaging body 20, thereby strengthening bonding between the substrate and the packaging body 20 and preventing delamination from occurring therebetween.

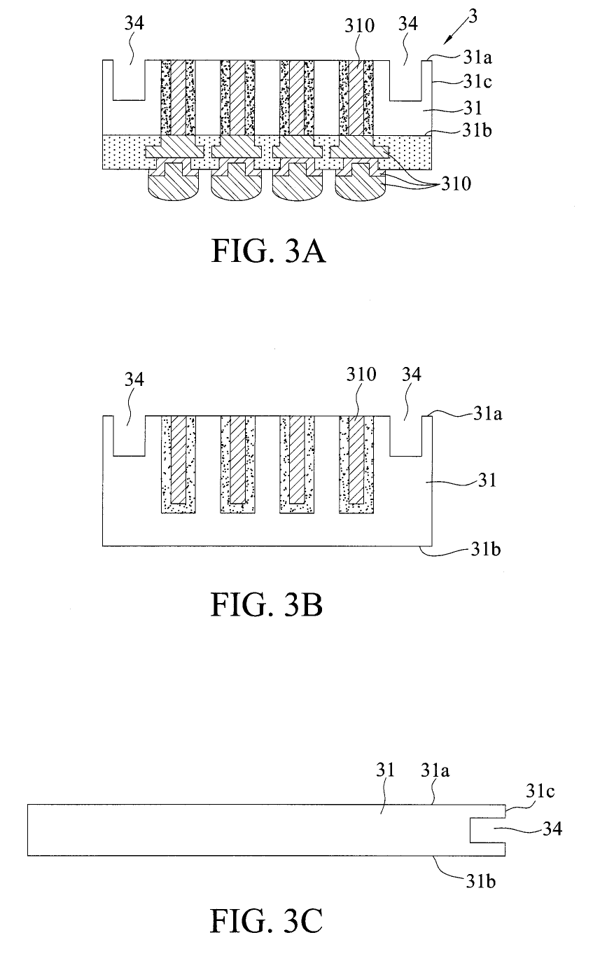

FIG. 3A is a schematic cross-sectional view of a substrate structure 3 according to the present disclosure. The substrate structure 3 of FIG. 3A can serve as the first substrate 21, the second substrate 22 or the third substrate 23 having the receiving space 24 in FIG. 2.

The substrate structure 3 has a substrate 31 having a plurality of conductors 310, and at least a receiving space 34 formed on a surface of the substrate 31, without penetrating the substrate 31.

In an embodiment, the substrate 31 is a ceramic board or a semiconductor board. In another embodiment, the substrate 31 is a board made of an organic material such as glass fiber, or a printed circuit board. The conductors 310 are circuit layers, conductive posts or conductive bumps.

In an embodiment, the substrate 31 has a first surface 31a, a second substrate 31b opposite to the first surface 31a, and a side surface 31c adjacent to and connecting the first surface 31a and the second surface 31b.

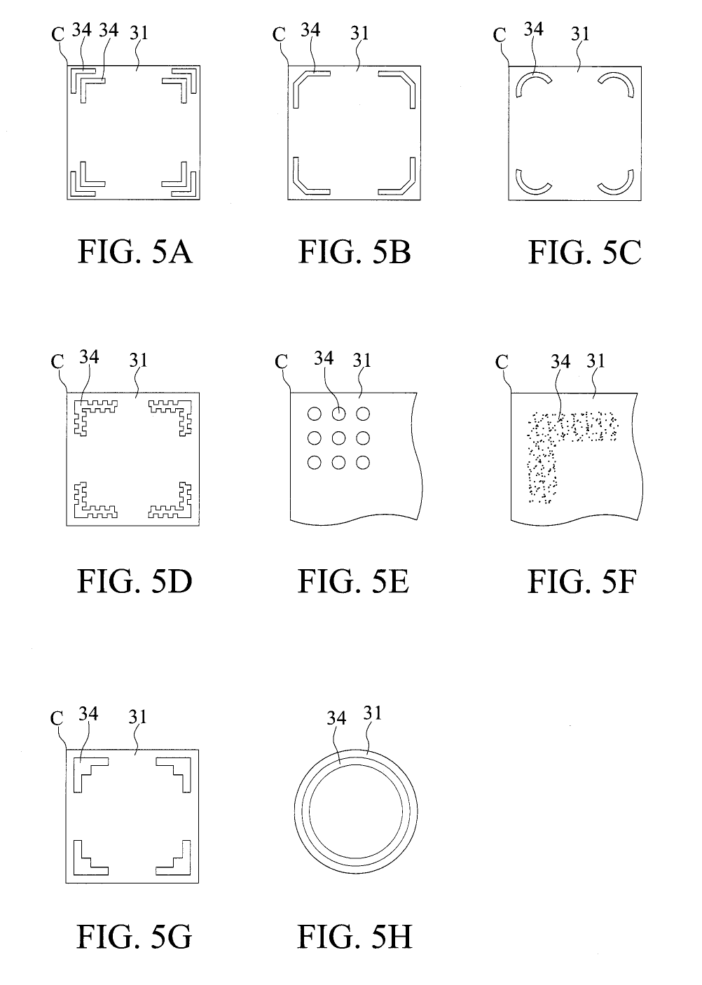

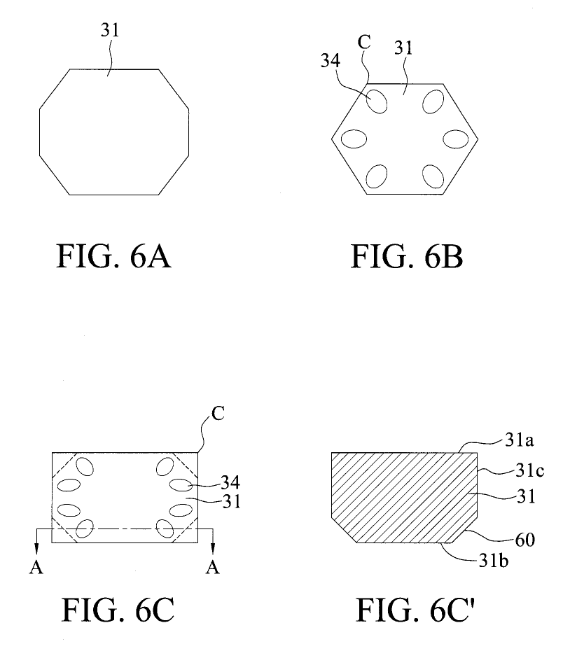

The substrate 31 can be in various shapes. In an embodiment, FIGS. 5A to 5H and FIGS. 6A to 6C are schematic upper views of a substrate structure according to various embodiments of the present disclosure. Referring to the drawings, the substrate 31 can be a board having, for example, a rectangular shape, a polygonal shape or a circular shape. Further, the substrate 31 can be a symmetrical or asymmetrical board. For example, referring to FIGS. 6C and 6C′, the first surface 31a and the second surface 31b of the substrate 31 are not symmetrical to each other since chamfers 60 are formed on corners between the second surface 31b and the side surface 31c of the substrate 31.

The receiving space 34 is formed on at least one of the first surface 31a, the second surface 31b and the side surface 31c of the substrate 31.

The receiving space 34 can be formed at various stages according to the practical need. In an embodiment, referring to FIG. 3A, the receiving space 34 is formed on the substrate 31 after the process for forming the conductors 310 of the substrate 31 is completed; or referring to FIG. 3B, the receiving space 34 is formed on the substrate 31 during the process for forming the conductors 310; or referring to FIG. 3C, the receiving space 34 is formed on the substrate 31 before formation of the conductors 310.

In an embodiment, the receiving space 34 can be formed by blasting (as shown in FIG. 5F, to increase the surface roughness), filing (as shown in FIG. 5F), cutting, drilling, milling, grinding, ultrasonic grinding, chemical-mechanical polishing (CMP), laser, water jet cutter, isotropic/anisotropic etching, dry/wet etching or a combination thereof. Therein, if the receiving space 34 is formed by etching, no linear vertical angle is formed in the receiving space 34.

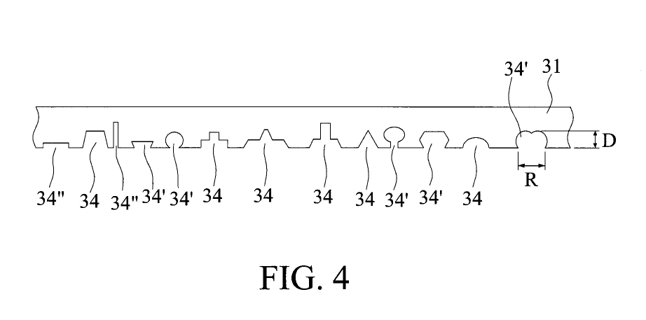

Referring to FIG. 4, the size of the receiving space 34 can be varied according to the material type of the packaging body 20. That is, the depth to width ratio of the receiving space 34 allows material particles of the packaging body to freely go in and out of the receiving space, without causing any flow blockage. For example, if filler particles of the packaging body 20 have a maximum size of 3 μm, preferably, the width R of the opening of the receiving space 34′ is greater than 3 μm (for example, the width R is 10 μm) and the depth D of the receiving space 34′ is about 3 to 6 μm. The width R of the opening of the receiving space 34, 34′, 34″ should be greater than the particle size of fillers of the packaging body.

Further, the receiving space 34 can have various shapes. Referring to FIG. 4, the receiving spaces 34, 34′, 34″ have different shapes in a side view. Alternatively, referring to FIGS. 5A to 5H, the receiving spaces 34 have various geometric shapes in an upper view. In an embodiment, referring to FIG. 4, the receiving space 34, if having a wide opening and a narrow inner portion, strengthens flow of the packaging body 20 in the receiving space 34; on the other hand, the receiving space 34′, if having a narrow opening and a wide inner portion, strengthens bonding between the packaging body 20 and the receiving space 34 (i.e., between the packaging body 20 and the substrate 31).

Further, the position of the receiving space 34 can be designed according to the practical need. In an embodiment, the receiving space 34 can be formed at regions where stress concentration likely occurs during processing of the substrate structure 3 so as to avoid delamination. In particular, referring to FIGS. 5A to 5G after a packaging process, large corner stresses likely occur at corners C of the substrate 31 and thus large stresses occur between the substrate 31 and the packaging body 20. Accordingly, the receiving space 34 can be formed at the corners C.

In the electronic package and substrate structure according to the present disclosure, the receiving space facilitates to strengthen the bonding between the substrate and the packaging body, thereby preventing delamination from occurring therebetween.

The above-described descriptions of the detailed embodiments are only to illustrate the implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. A substrate structure, comprising:
a substrate having a plurality of conductors; and
at least a receiving space formed on a surface of the substrate with the receiving space free from penetrating the substrate.

2. The substrate structure of claim 1, wherein the substrate is a semiconductor board or a ceramic board.

3. The substrate structure of claim 1, wherein the substrate has a first surface, a second surface opposite to the first surface, and a side surface adjacent to and connecting the first surface and the second surface, and the receiving space is formed on at least one of the first surface, the second surface and the side surface of the substrate.

4. The substrate structure of claim 1, wherein the substrate has at least a corner, and the receiving space is formed at the corner.

5. The substrate structure of claim 1, wherein the conductors are circuit layers, conductive posts, conductive bumps, or any combination thereof.

6. The substrate structure of claim 1, wherein the receiving space has an opening greater than 3 μm in width.

7. The substrate structure of claim 1, wherein the receiving space has an opening with a width greater than a width of an inner portion of the receiving space.

8. The substrate structure of claim 1, wherein the receiving space has an opening with a width smaller than a width of an inner portion of the receiving space.

9. An electronic package, comprising:
at least a first substrate having a plurality of first conductors;
at least a second substrate bonded to the first substrate and having a plurality of second conductors;
at least a receiving space formed on a surface of the first substrate or the second substrate with the receiving space free from penetrating the first substrate and the second substrate; and
a packaging body formed on the first substrate and filling the receiving space with a filler of the packaging body.

10. The electronic package of claim 9, wherein at least one of the first substrate and the second substrate is a semiconductor board or a ceramic board.

11. The electronic package of claim 9, wherein the first substrate has a first surface, a second surface opposite to the first surface, and a side surface adjacent to and connecting the first surface and the second surface, and the receiving space is formed on at least one of the first surface, the second surface and the side surface of the first substrate.

12. The electronic package of claim 9, wherein the second substrate has a third surface, a fourth surface opposite to the third surface, and a side surface adjacent to and connecting the third surface and the fourth surface, and the receiving space is formed on at least one of the third surface, the fourth surface and the side surface of the second substrate.

13. The electronic package of claim 9, wherein at least one of the first substrate and the second substrate has at least a corner, and the receiving space is formed at the corner.

14. The electronic package of claim 9, wherein the first conductors and the second conductors are circuit layers, conductive posts, conductive bumps, or any combination thereof.

15. The electronic package of claim 9, wherein the first conductor are electrically connected to the second conductors.

16. The electronic package of claim 9, wherein the receiving space has an opening with a width greater than a particle size of the filler of the packaging body.

17. The electronic package of claim 9, wherein the receiving space has an opening greater than 3 μm in width.

18. The electronic package of claim 9, wherein the receiving space has an opening with a width greater than a width of an inner portion of the receiving space.

19. The electronic package of claim 9, wherein the receiving space has an opening with a width smaller than a width of an inner portion of the receiving space.

20. The electronic package of claim 9, wherein the packaging body covers the first substrate and/or the second substrate.

21. The electronic package of claim 9, further comprising at least a third substrate bonded to the second substrate.

22. The electronic package of claim 21, wherein the receiving space is formed on the first substrate, the second substrate and/or the third substrate with the receiving space free from penetrating the first substrate, the second substrate and the third substrate.
